(19) United States
(12) Patent Application Publication
(10) Pub. No.: US 2005/0041405 A1
(43) Pub. Date: Feb. 24, 2005

(54) Stacked via structure that includes a skip via

(75) Inventor: Daisuke Kawagoe, Chiba Perfecture (JP)

Correspondence Address: Schwegman, Lundberg, Woessner & Kluth, P.A., P.O. Box 2938, Minneapolis, MN, 55402, US

(73) Assignee: Intel Corporation

(21) Appl. No.: 10/646,478

(22) Filed: Aug. 22, 2003

(51) Int. Cl. H05K 1/11

(52) U.S. Cl. 361/783; 361/795; 174/262

(57) ABSTRACT

In various embodiments, the present invention relates to a substrate that may include vias for communicating signals throughout the substrate. The substrate includes a plurality of dielectric layers and a stack of vias that may be formed on a core. One of the vias may be a first skip via that extends through at least two of the dielectric layers, while another via may extend through at least one other of the dielectric layers. The second via and the first skip via are stacked on top of one another. In another sample embodiment of the substrate, the second via may be a second skip via that extends through at least two dielectric layers.

### TECHNICAL FIELD

Various embodiments of the present invention relate to a substrate for electronic devices that include a stacked via structure.

### BACKGROUND

Signals may be transmitted between layers in a substrate using vias. The vias may be stacked one on top of another depending on the design of the substrate.

Stacked vias tend to crack or delaminate at the interfaces between the vias when the vias are subjected to stress. When a via cracks or delaminates, the electronic assemblies that include such substrates may fail.

Cracking in a stacked via may also increase the resistance of the current path formed by the stacked via. The increased resistance of the stacked via may generate unwanted heat within the stacked via during operation of the substrate.

Stacked vias may be used in substrates that include a relatively high number of dielectric layers. As the number of via-to-via interfaces in a stack increases, the risk that one of the vias will crack and/or delaminate may also increase.

One technique that may be used to minimize stress throughout a stack of vias is to utilize dielectric materials in the layers of the substrate that have a lower coefficient of thermal expansion (CTE). However, the stress within the stacked via structure may not be completely eliminated when lower CTE materials are used to form the dielectric layers in a substrate.

There is a need for a substrate that includes stacked vias which are able to reliably communicate signals between dielectric layers in the substrate. The number of via-to-via interfaces within the stack of vias should be minimized to decrease cracking and/or delamination that may occur within the stacked via.

### BRIEF DESCRIPTION OF THE DRAWINGS

A more complete understanding may be derived by referring to the detailed description and associated figures. It should be noted that like reference numbers refer to similar items throughout the figures.

FIG. 1 is a section view illustrating a portion of a substrate that includes stacked vias.

FIG. 2 is a section view illustrating a portion of another substrate that includes stacked vias.

FIG. 3 is a section view illustrating a portion of the substrate shown in FIG. 2 with an additional via added to the stacked vias.

FIGS. 4A-4H are section views that illustrate a method of forming the substrate shown in FIG. 1.

FIG. 5 is a block diagram of an electronic system incorporating at least one substrate similar to the substrates shown in FIGS. 1-3.

### DETAILED DESCRIPTION

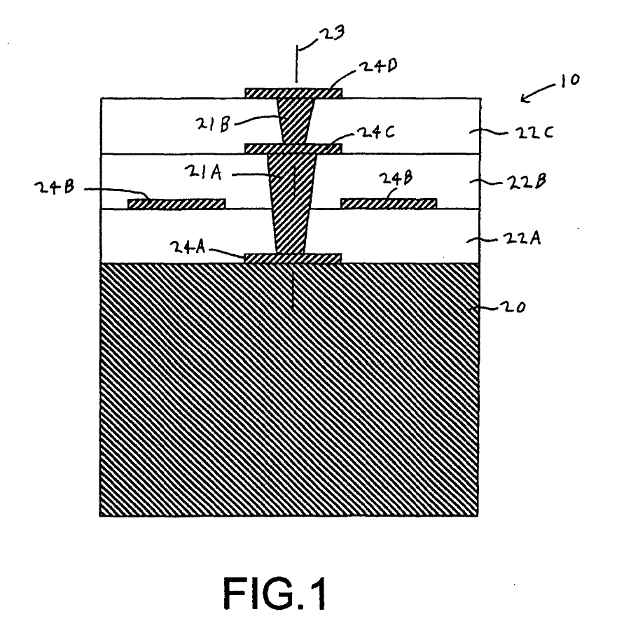

FIG. 1 illustrates a substrate 10 that may include vias 21A, 21B for communicating signals throughout the substrate 10, in accordance with various embodiments of the invention. Substrate 10 may include a plurality of dielectric layers 22A, 22B, 22C that are formed on a core 20. One of the vias 21A, 21B may be a first skip via 21A that extends through at least two of the dielectric layers 22A, 22B. Another via 21B may extend through at least one other of the dielectric layers 22C such that the second via 21B and the first skip via 21A are stacked on top of one another.

As used herein, vias that are stacked refers to vias that at least partially overlap. The sample embodiment illustrated in FIG. 1 shows that the longitudinal axis 23 of each via 21A, 21B may be substantially aligned with the longitudinal axis of the other vias.

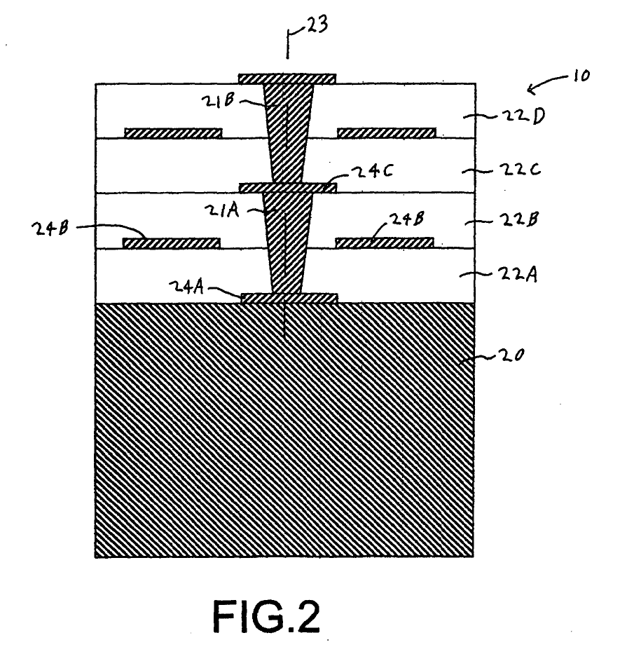

FIG. 2 illustrates another sample embodiment of substrate 10. In the example embodiment illustrated in FIG. 2, the second via 21B may be a second skip via 21B that extends through at least two dielectric layers 22C, 22D.

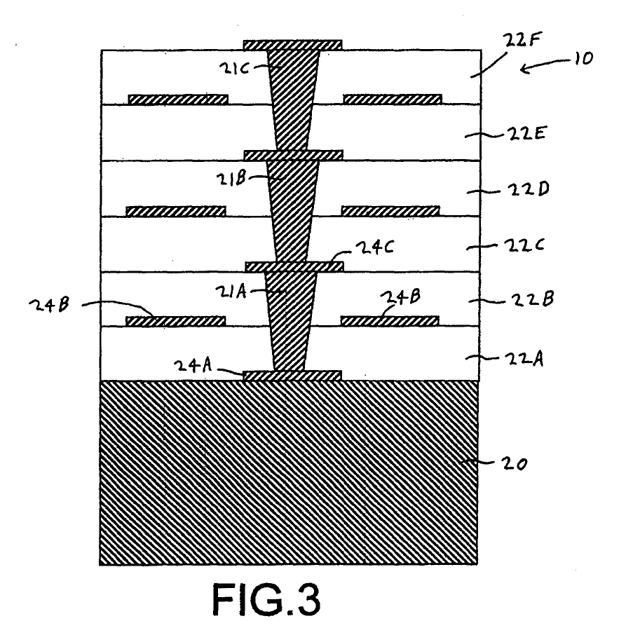

FIG. 3 illustrates another sample embodiment of substrate 10. In the example embodiment illustrated in FIG. 3, substrate 10 may include a third via 21C that extends through at least one other of the dielectric layers 22E, 22F such that the third via 21C may be stacked onto the first skip via 21A and the second skip via 21B. As shown in FIG. 3, third via 21C may be a skip via 21C that extends through at least two dielectric layers 22E, 22F.

Depending on the design of the substrate 10, any number of vias may be included in the stack of vias as long as at least one of the vias is a skip via. In addition, the skip via may be located anywhere within the stack of vias (e.g., top, bottom, or somewhere in the middle). The stack of vias may also include more than one skip via. It should be noted that a skip via may extend through two or more dielectric layers.

Utilizing one or more skip vias in a stack of vias reduces the number of via-to-via interfaces within the stack of vias. The via-to-via interfaces within a stack of vias are the sections within the stack of vias that tend to crack or delaminate when the vias are subjected to stress. Therefore, reducing the number of via-to-via interfaces within the stack of vias may make electronic assemblies that include such substrates less likely to fail.

FIGS. 1, 2 and 4A-4H illustrate a method in accordance with various embodiments of the invention. As shown in FIG. 1, the method may include forming a first via 21A and stacking a second via 21B onto the first via 21A. Although first via 21A is shown as skip via 21A, either the first via 21A or the second via 21B may be a skip via.

FIG. 2 illustrates that stacking a second via 21B onto the first via 21A may include stacking a second skip via 21B onto the first skip via 21A. In addition, stacking the second via 21B onto the first via 21A may include substantially aligning a longitudinal axis 23 of the first via 21A with a longitudinal axis 23 of the second via 21B.

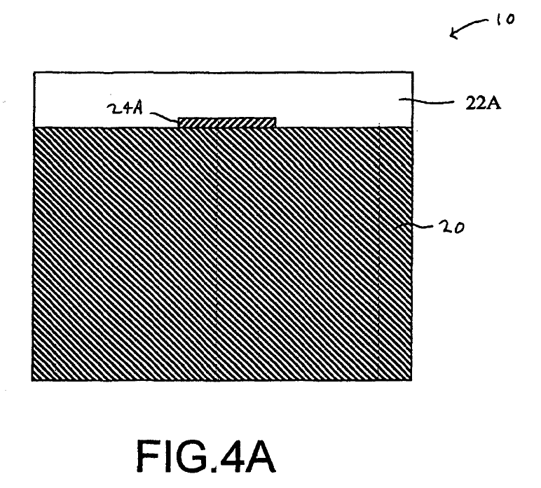

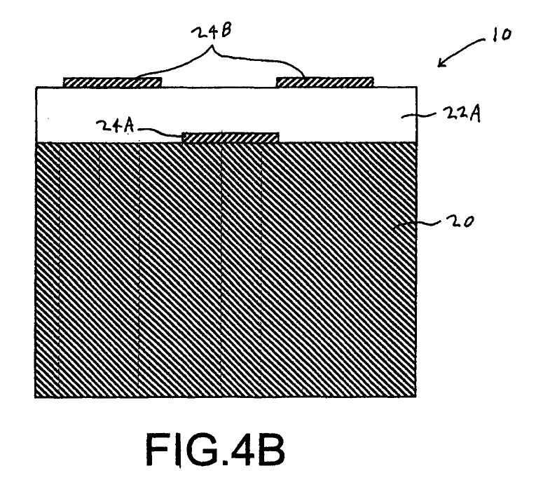

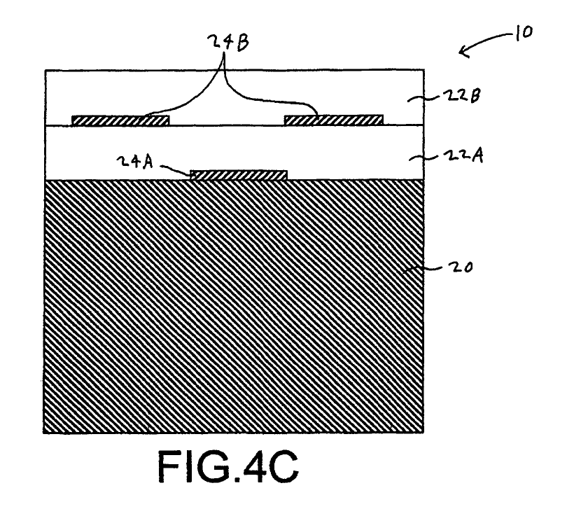

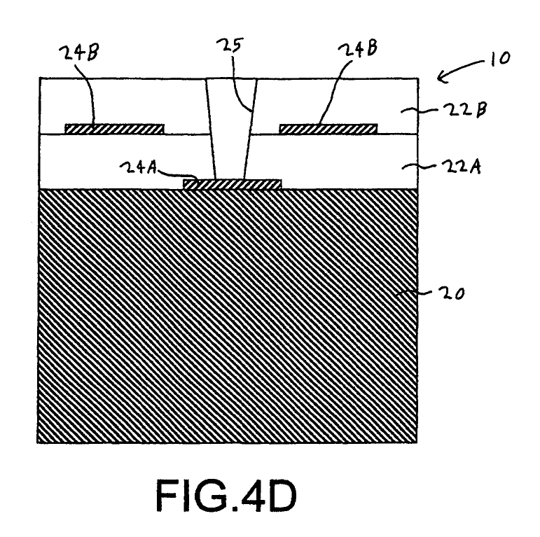

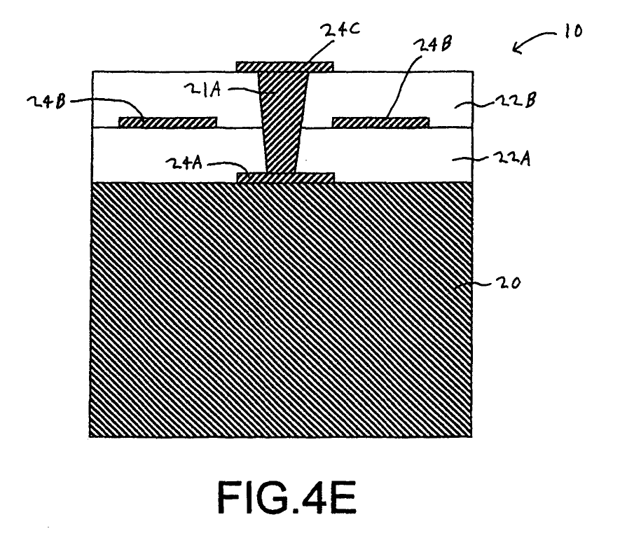

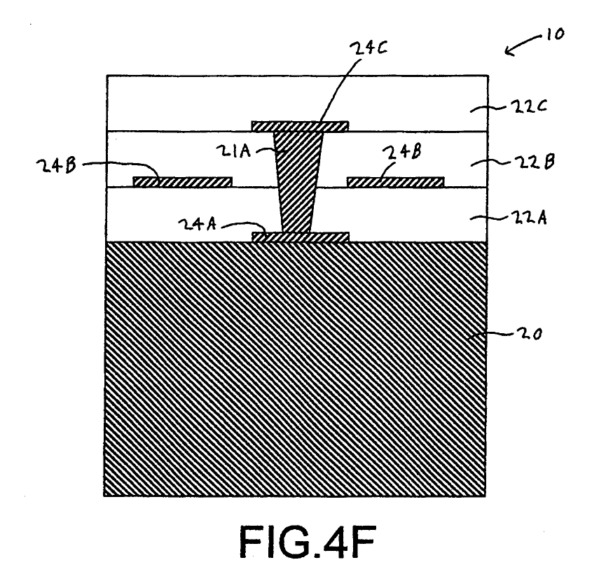

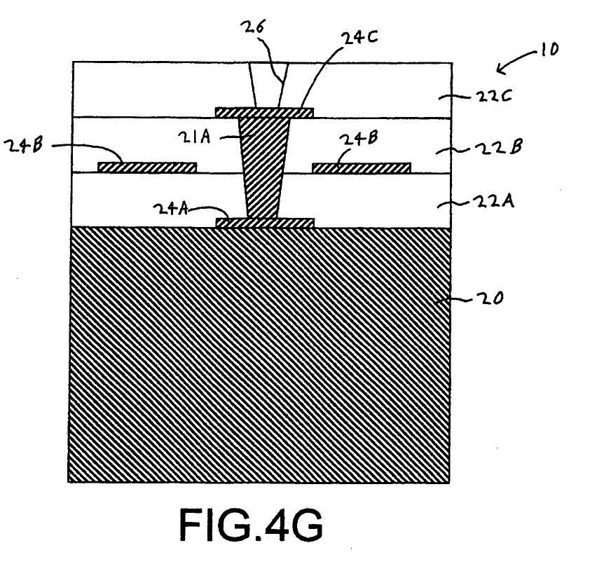

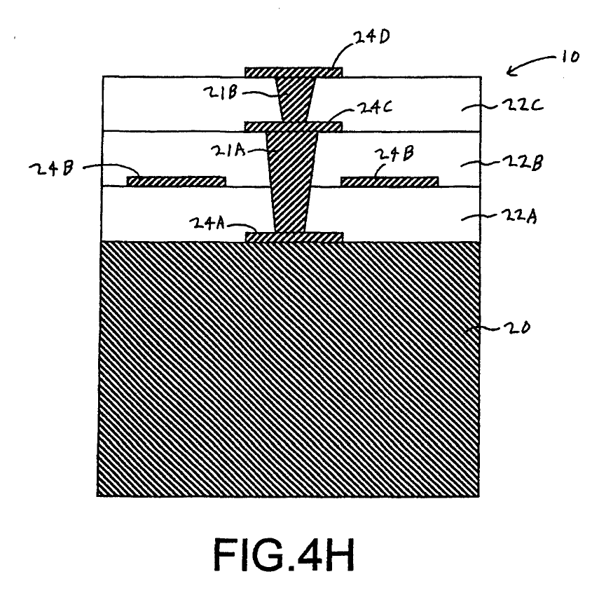

FIGS. 4A-4G illustrate that forming a first via 21A in a substrate 10 may include forming a first conductive layer 24A onto a core 20 and forming a first dielectric layer 22A such that the first conductive layer 24A is between the first dielectric layer 22A and the core 20 (FIG. 4A). In various embodiments, forming a first conductive layer 24A may include plating the first conductive layer 24A onto the first dielectric layer 22A and patterning the first conductive layer 24A to form traces on the core 20.

Forming a first via 21A may further include forming a second conductive layer 24B onto the first dielectric layer 22A (FIG. 4B). The method may further include forming a second dielectric layer 22B such that the second conductive layer 24B is between the first dielectric layer 22A and the second dielectric layer 22B (FIG. 4C). In various embodiments, forming a second conductive layer 24B may include plating the second conductive layer 24B onto the first dielectric layer 22A and patterning the second conductive layer 24B to form traces on the first dielectric layer 22A.

Forming a first via 21A may further include forming an opening 25 in the first and second dielectric layers 22A, 22B (FIG. 4D). The method may further include forming a first skip via 21A in the opening 25 (FIG. 4E).

In addition, forming a first skip via 21A in the opening 25 may include filling the opening 25 with a conductive material, such as by forming a third conductive layer 24C onto the second dielectric layer 22B (FIG. 4E). In various embodiments, forming a third conductive layer 24C may include plating the third conductive layer 24C onto the second dielectric layer 22B. The method may further include patterning the third conductive layer 24C to form traces on the second dielectric layer 22B.

Forming the opening 25 in the first and second dielectric layers 22A, 22B may include drilling an opening 25 in the first and second dielectric layers 22A, 22B, such as by laser drilling. In alternative embodiments, forming the opening 25 in the first and second dielectric layers 22A, 22B may include etching the opening 25 in the first and second dielectric layers 22A, 22B.

In the example embodiment shown in FIG. 4F, the first via 21A is a first skip via 21A such that stacking the second via 21B onto the first skip via 21A may include forming a third dielectric layer 22C on the third conductive layer 24C. The method may further include forming a second opening 26 in the third dielectric layer 22C (FIG. 4G), and forming the second via 21B in the opening 26 (FIGS. 1 and 4H).

In various embodiments, forming the second via 21B in the opening 26 may include filling the opening 26 with a conductive material. The opening 26 may be filled by forming a fourth conductive layer 24D onto the third dielectric layer 22C, and then patterning the fourth conductive layer 24D to form traces on the third dielectric layer 22C.

The example methods described herein may be suitable for reducing the number of steps associated with fabricating substrates that have stacked vias. The number of steps associated with fabricating such substrates is reduced because forming one or more skip vias in a stack of vias decreases the number of drilling operations that need to be carried out in order to form the stack of vias.

The vias may be cylindrical or any other shape that facilitates fabricating substrate 10. In some embodiments, each of the vias is cylindrical with a diameter between 49 um and 85 um. The skip vias that extend through two dielectric layers may have a length between 58 um and 92 um, while the other regular vias may have a length between 24 um and 36 um.

Various conductive materials may be used for vias 21A, 21B, 21C and/or the conductive layers. These materials may include gold, copper, aluminum and combinations thereof.

In some embodiments, each of the conductive layers is applied to the respective dielectric layers such that the conductive layers have a thickness between 10 um and 75 um. The conductive layers may be applied at the same thickness, different thicknesses, or any combination thereof.

Various materials may be used for dielectric layers 22A-22F. In various embodiments, these materials may include film and liquid type insulation materials that are made of resin plus filler. The CTE value of the dielectric layers 22A-22F is typically controlled by filler content and the type of resin.

In some example embodiments, each of the dielectric layers 22A-22F has a thickness between 34 um and 111 um. The dielectric layers that form the substrate 10 may have the same thickness, different thicknesses, or any combination thereof.

Various materials may be used for core 20. In various embodiments, these materials may include one or more different types of resins. In some embodiments, the resins that form the core 20 may further include glass fiber cloth with one or more fillers.

The core 20 may have any thickness. In some example embodiments, the core 20 has a thickness between 650 um and 850 um.

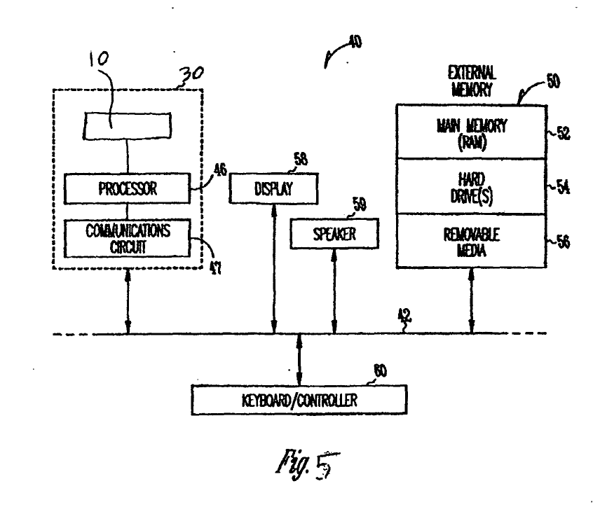

FIG. 5 is a block diagram of an electronic system 40 incorporating at least one electronic assembly 30. The electronic assembly 30 may include any of the example substrates 10 described above. Electronic system 40 may be a computer system that includes a system bus 42 to electrically couple the various components of electronic system 40 together. System bus 42 may be a single bus or any combination of busses.

Electronic assembly 30 is electrically coupled to system bus 42 and may include any circuit, or combination of circuits. In one embodiment, electronic assembly 30 includes a processor 46 that is coupled to substrate 10. As used herein, processor means any type of circuit, such as, but not limited to, a microprocessor, a microcontroller, a graphics processor or a digital signal processor. Other types of circuits that can be coupled to substrate 10 in electronic assembly 30 are a custom circuit or an application-specific integrated circuit, such as communications circuit 47 for use in wireless devices such as cellular telephones, pagers, portable computers, two-way radios, and similar electronic systems.

The electronic system 40 may also include an external memory 50 that in turn may include one or more memory elements suitable to the particular application, such as a main memory 52 in the form of random access memory (RAM), one or more hard drives 54, and/or one or more drives that handle removable media 56, such as diskettes, compact disks (CDs) and digital video disks (DVDs).

The electronic system 40 may also include a display device 58, a speaker 59, and a controller 60, such as a keyboard, mouse, trackball, game controller, microphone, voice-recognition device, or any other device that inputs information into the electronic system 40.

As shown herein, substrate 10 can be implemented in a number of different embodiments, including an electronic package, an electronic system and a computer system. The elements, materials, geometries and dimensions can all be varied to suit particular requirements.

FIGS. 1-5 are merely representational and are not drawn to scale. Certain proportions thereof may be exaggerated while others may be minimized.

Many other embodiments will be apparent to those of skill in the art from the above description. Modifications, equivalents and variations are within the scope of the appended claims.

1. A method comprising:
forming a first via; and
stacking a second via onto the first via, at least one of the first via and the second via being a skip via.

2. The method of claim 1 wherein stacking a second via onto the first via includes stacking a second skip via onto a first skip via.

3. The method of claim 1 wherein stacking the second via onto the first via includes substantially aligning a longitudinal axis of the first via with a longitudinal axis of the second via.

4. The method of claim 1 wherein forming a first via comprises:
forming a first conductive layer onto a core;
forming a first dielectric layer such that the first conductive layer is between the first dielectric layer and the core;
forming a second conductive layer onto the first dielectric layer;
forming a second dielectric layer such that the second conductive layer is between the first dielectric layer and the second dielectric layer;
forming an opening in the first and second dielectric layers; and
forming a first skip via in the opening.

5. The method of claim 4 wherein forming an opening in the first and second dielectric layers includes drilling an opening in the first and second dielectric layers.

6. The method of claim 5 wherein drilling an opening in the first and second dielectric layers includes laser drilling an opening in the first and second dielectric layers.

7. The method of claim 4 wherein forming an opening in the first and second dielectric layers includes etching an opening in the first and second dielectric layers.

8. The method of claim 4 wherein forming a first conductive layer includes plating the first conductive layer onto the core and patterning the first conductive layer, and wherein forming a second conductive layer includes plating the second conductive layer onto the first dielectric layer and patterning the second conductive layer.

9. The method of claim 4 wherein forming the first skip via in the opening includes filling the opening with a conductive material.

10. The method of claim 9 wherein filling the opening with a conductive material includes forming a third conductive layer onto the second dielectric layer.

11. The method of claim 4 wherein forming a third conductive layer on the second dielectric layer includes patterning the third conductive layer.

12. The method of claim 10 further comprising:
forming a third dielectric layer on the third conductive layer;
forming a second opening in the third dielectric layer; and
forming the second via in the second opening.

13. The method of claim 12 wherein forming the second via in the second opening includes forming a fourth conductive layer onto the third dielectric layer.

14. A substrate comprising:
a plurality of dielectric layers;
a first skip via extending through two of the dielectric layers; and
a second via extending through one of the dielectric layers, the second via and the first skip via being stacked on top of one another.

15. The substrate of claim 14 wherein the second via is a second skip via extending through two of the dielectric layers.

16. The substrate of claim 14 wherein the first skip via includes a longitudinal axis and the second via includes a longitudinal axis, the longitudinal axis of the first skip via being substantially aligned with the longitudinal axis of the second via.

17. The substrate of claim 14 further comprising a third via extending through at least one of the dielectric layers, the third via being stacked onto the first skip via and the second via.

18. The substrate of claim 14 wherein the plurality of dielectric layers is formed on a core.

19. A computer system comprising:
a bus;
a memory coupled to the bus; and
a substrate electrically coupled to the bus, the substrate including a plurality of dielectric layers, a first skip via extending through two of the dielectric layers and a second via extending through one of the dielectric layers, the second via and the first skip via being stacked on top of one another.

20. The computer system of claim 19 wherein the second via is a second skip via extending through two of the dielectric layers.

21. The computer system of claim 19 further comprising a processor coupled to the substrate and the bus.
